(19) United States
(12) Patent Application Publication
(10) Pub. No.: US 2006/0279314 A1
(43) Pub. Date: Dec. 14, 2006

(54) Test supporting device and method of testing using the same

(75) Inventors: Il-Chan Park, Hwaseong-si (KR); Young-Bu Kim, Seongnam-si (KR); Seung-Ki Nam, Suwon-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 11/437,621

(22) Filed: May 22, 2006

(30) Foreign Application Priority Data
Jun. 8, 2005 (KR) 10-2005-0048822

(51) Int. Cl. G01R 31/26

(52) U.S. Cl. 324/765

(57) ABSTRACT

Provided are example embodiments of a test supporting device including a radio frequency (RF) line adapted to transmit an RF signal from an RF terminal to test equipment, a direct current (DC) line connected to the RF line at a first end and adapted to connect to the test equipment at a second end, and a capacitor connected to the DC line at a first end and connected to ground at a second end. Example embodiments of the present invention may also provide a test method including measuring a radio frequency (RF) signal, and measuring a direct current (DC) signal passed through an open stub.

### PRIORITY CLAIM

A claim of priority is made to Korean Patent Application No. 10-2005-0048822, filed on Jun. 8, 2005, in the Korean Intellectual Property Office, the disclosure of which is incorporated herein in its entirety by reference.

### BACKGROUND OF THE INVENTION

1. Field of the Invention

Example embodiments of the present invention may relate to a device used to test a radio frequency (RF) device, and a method of testing using the device. More particularly, example embodiments of the present invention relate to a test supporting device used to test RF and DC signals of an RF device, and a method of testing RF and DC signals of the RF device.

2. Description of the Related Art

FIG. 1 is a block diagram of a radio frequency (RF) test system according to the conventional art. An RF test system 10 may include an RF device 11 and auto-test equipment (ATE) 12. An RF signal terminal (or pin) of the RF device 11 may be connected to an RF port of the ATE 12 via an RF line 15 to measure characteristics of a signal output from the RF device 11. The ATE 12 may be capable of measuring characteristics of an RF signal received from the RF port via the RF line 15, but may not be capable of receiving a direct current (DC) signal from the RF port, because an amplitude of a signal to be received by the RF port is limited to several mV. Accordingly, when a DC signal is input to the RF port, an internal circuit thereof may be damaged. Therefore, the RF line 15 may include a capacitor (not shown) to prevent DC signals from entering the RF port.

Also, a DC line 16 may be additionally connected to the ATE 12 to separately measure the DC signal. However, as illustrated in FIG. 1, when the ATE 12 receives the DC signal from the RF signal terminal of the RF device 11 via the DC line 16, which is also connected to the RF line 15, the RF line 15 may be affected. The connection of the DC line 16 to the RF line 15 may cause resonance to occur in a signal transmitted along the RF line 15, and may interfere with normal signal transmission along the RF line 15 due to a reduction in power. Recently, to avoid interference, the DC line 16 has not been connected to the RF line 15.

FIGS. 2A and 2B are graphs illustrating characteristics of an RF signal transmitted at a frequency band between 0 to 3 GHz when a DC line is added to an RF system of FIG. 1 versus a RF system without a DC line 16. The RF line 15 may be 50 mm long and the DC line 16 may be 220 mm long. Referring to FIG. 2A, the amount of signal reflection 21 is −40 db or less when the DC line 16 is not present, whereas the amount of signal reflection 22 is −40 db or more when the DC line 16 is present. Referring to FIG. 2B, an amount of signal loss 25 may be very small when the DC line 16 is not present, whereas an amount of signal loss 26 may be great due to transmission loss caused by resonance in the RF signal when the DC line 16 is present. Accordingly, there had been problems performing DC tests with respect to the RF signal terminal of the RF device.

The performance of the RF signal terminal cannot be sufficiently evaluated just by measuring the characteristics of the RF signal. In other words, the higher the frequency band of the RF signal transmitted from the RF device 11, the greater the coupling effect of adjacent signals. Accordingly, when the RF signal is not connected to the internal circuit but may be affected by signal outputs from adjacent terminals, the RF signal terminal may be regarded as normally outputting the RF signal.

For example, in a normal situation, an RF signal terminal may be connected to an internal circuit via a bonding wire. If an error occurs during bonding, the bonding wire may be separated from a bonding pad connected to the RF signal terminal. However, according to the above transmission characteristics of the RF signal, it may be difficult to detect a faulty RF signal terminal because the RF signal may be induced to the faulty RF signal terminal via an adjacent bonding wire, terminal, or pin. Although a simple open/short test may be performed to detect a faulty RF signal terminal, there may be problems preventing the faulty RF signal terminal from being accurately detected.

### SUMMARY OF THE INVENTION

Example embodiments of the present invention may provide a test supporting device capable of securing a frequency band for a radio frequency (RF) test without causing resonance in an RF signal even when a direct current (DC) line for a DC test is added to an RF line.

Example embodiments of the present invention may also provide a test method of measuring an RF signal and a DC signal received from an RF signal terminal by using an RF line and a DC line connected to the RF line.

Example embodiments of the present invention may perform a DC test on a RF signal terminal to check the connection state of an internal circuit to the RF signal terminal that outputs the RF signal, or the connection state of the RF signal terminal.

In an example embodiment of the present invention, a test supporting device may include a radio frequency (RF) line adapted to transmit an RF signal from an RF terminal to test equipment, a direct current (DC) line connected to the RF line at a first end and adapted to connect to the test equipment at a second end, and a capacitor connected to the DC line at a first end and connected to ground at a second end.

In another example embodiment, a test supporting device may include a radio frequency (RF) line adapted to transmit an RF signal from an RF terminal to test equipment, an impedance matching circuit provided in the RF line, a direct current (DC) line connected to the RF line at a first end and adapted to connect to the test equipment at a second end, a capacitor connected to the DC line at a first end and connected to ground at a second end, and an auxiliary circuit provided in the DC line and configured to alter resonance characteristics of the RF signal.

In an example embodiment of the present invention, a test method may include measuring a radio frequency (RF) signal, and measuring a direct current (DC) signal passed through an open stub.

### BRIEF DESCRIPTION OF THE DRAWINGS

Example embodiments of the present invention may become more apparent with the description of the detail example embodiments thereof with reference to the attached drawings in which:

FIG. 1 is a block diagram of a radio frequency (RF) test system used to tests an RF device according to the conventional art;

FIG. 2A is a graph illustrating an amount of RF signal reflection when a direct current (DC) line for a DC test is present in the RF system of FIG. 1 versus when a DC line is not present;

FIG. 2B is a graph illustrating an amount of RF signal loss when a DC line for the DC test is present in the RF system of FIG. 1 versus when a DC line is not present;

FIG. 3 is a block diagram of a test supporting device according to an example embodiment of the present invention;

FIG. 4A is an example graph illustrating an amount of RF signal reflection when a capacitor is present in a DC line of the test supporting device of FIG. 3 versus when a capacitor is not present;

FIG. 4B is an example graph illustrating an amount of RF signal loss when a capacitor is present in a DC line of the test supporting device of FIG. 3 versus when a capacitor is not present;

FIG. 5A is an example graph illustrating an amount of RF signal reflection according to the location of the capacitor;

FIG. 5B is an example graph illustrating an amount of RF signal loss according to the location of the capacitor;

FIG. 6 is a block diagram of a test supporting device according to another example embodiment of the present invention;

FIG. 7A is an example graph illustrating an amount of RF signal reflection when only a capacitor is present in the test supporting device of FIG. 6 versus when both the capacitor and an auxiliary circuit are present;

FIG. 7B is an example graph illustrating an amount of RF signal loss when only a capacitor is present in the test supporting device of FIG. 6 versus when both the capacitor and an auxiliary circuit are present;

FIG. 8A is an example graph illustrating an amount of RF signal reflection when only a capacitor is present in the test supporting device of FIG. 6 versus when both the capacitor and the auxiliary circuit are present; and

FIG. 8B is an example graph illustrating an amount of RF signal loss when only a capacitor is present in the test supporting device of FIG. 6 versus when both the capacitor and the auxiliary circuit are present.

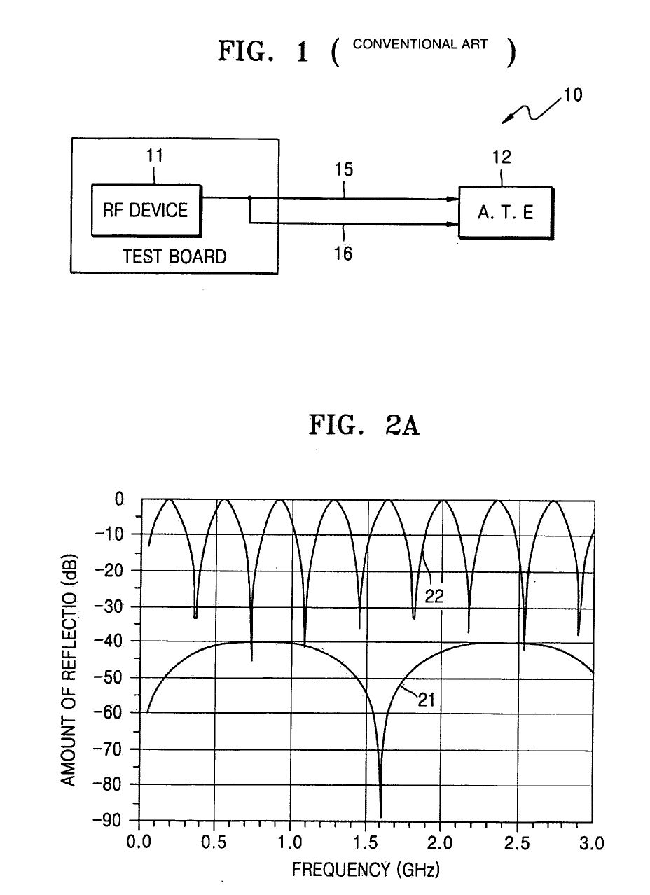

### DETAILED DESCRIPTION OF THE EXAMPLE EMBODIMENT OF THE PRESENT INVENTION

Hereinafter, example embodiments of the present invention will be described in detail with reference to the accompanying drawings. Like reference numerals designate like elements throughout the specification.

It will be understood that when an element or layer is referred to as being on”, “connected to” or “coupled to” another element or layer, it may be directly on, connected or coupled to the other element or layer or intervening elements or layers may be present. In contrast, when an element is referred to as being “directly on,” “directly connected to” or “directly coupled to” another element or layer, there may be no intervening elements or layers present. Like numbers refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms may be only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present invention. As used herein, the singular forms “a”, “an” and “the” may be intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments of the present invention are described herein with reference to cross-section illustrations that may be schematic illustrations of idealized embodiments (and intermediate structures) of the present invention. As such, variations from the shapes of the illustrations as a result, for example, of manufacturing techniques and/or tolerances, are to be expected. Thus, the example embodiments of the present invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

FIG. 3 is a block diagram of a test supporting device according to an example embodiment of the present invention. A test supporting device 30 may include an impedance matching circuit 33, a radio frequency (RF) line 34, a direct current (DC) line 35, and a capacitor 36.

The test supporting device 30 may be connected between an RF signal terminal of an RF device (not shown) and auto-test equipment (ATE) (not shown) to perform both an RF test and a DC test on the RF signal terminal. In general, the RF signal terminal is connected to an internal circuit of the RF device via a bonding wire, but when an error occurs in a bonding process, for example, the bonding wire may be separated from a bonding pad connected to the RF signal terminal. The test supporting device 30 may be configured to detect a faulty RF signal terminal by performing a DC test together with an RF test. During an RF test, a DC signal output from an RF signal terminal may be removed and only an RF signal of several mV may be measured to determine whether the RF device is operating properly. During the DC test, a DC signal output from the RF signal terminal may be measured to determine whether the RF device is operating properly.

An impedance matching circuit 33 may be provided in an RF line 34 for the RF test. The impedance matching circuit 33 may include a plurality of passive elements (not shown) to match impedance of an input port of the ATE to that of the RF line 34. A capacitor (not shown) to remove DC signals may be included into either the impedance matching circuit 33 or the ATE. The operation of the impedance matching circuit 33 is well known to those of ordinary skill in the art, therefore, will not be described herein. During an RF test, the RF line 34 may be connected to a desired input port of the ATE, and the ATE may measure the RF signal received from the RF signal terminal via the RF line 34.

To perform the DC test together with the RF test, the DC line. 35 may be connected to a position A between the RF signal terminal and the impedance matching circuit 33 in the test supporting device 30. The capacitor 36 may be connected between the DC line 35 and ground. During the DC test, the DC line 35 may be connected to a desired input port of the ATE, and the ATE measures a DC signal received from the RF signal terminal via the DC line 35.

The ATE may measure the RF signal transmitted via the RF line 34 because the DC line 35 acts as an open stub due to the capacitor 36. The capacitance of the capacitor 36 may be set to a range that does not cause distortion of the DC signal. Distortion of the RF signal is not affected by the capacitor 36.

The capacitor 36 may be connected to a point B that is spaced a desired distance from point A of the RF line 34. The wavelength λ of the RF signal is computed by the frequency f of the RF signal and the characteristic values εᵣ, d, and W of the RF line 34, given by the following equations:

$$\begin{matrix}λ = \frac{1}{\sqrt{ɛ}} \frac{c}{f} & ( 1 ) \\ ɛ = \frac{{ɛ}_{r} + 1}{2} + \frac{{ɛ}_{r} - 1}{2} \frac{1}{\sqrt{1 + 12 d / W}} , & ( 2 )\end{matrix}$$

wherein εᵣ denotes the dielectric constant of a test board on which the RF line 34 may be installed, d denotes a distance between a grounding surface of the test board and the RF line 34, and W denotes the width of the RF line 34.

Equations (1) and (2) may be obtained when the RF line 34 is provided on a flat test board. If an environment in which the RF line 34 is provided changes, Equations (1) and (2) may be altered accordingly. Irrespective of the environment of the RF line 34, the capacitor 36 may be connected to point B that is spaced a desired distance from point A of the RF line 34 connected to the DC line 35. The desired distance may be one of ¼, 4/3, 5/4, etc., of the RF signal wavelength λ.

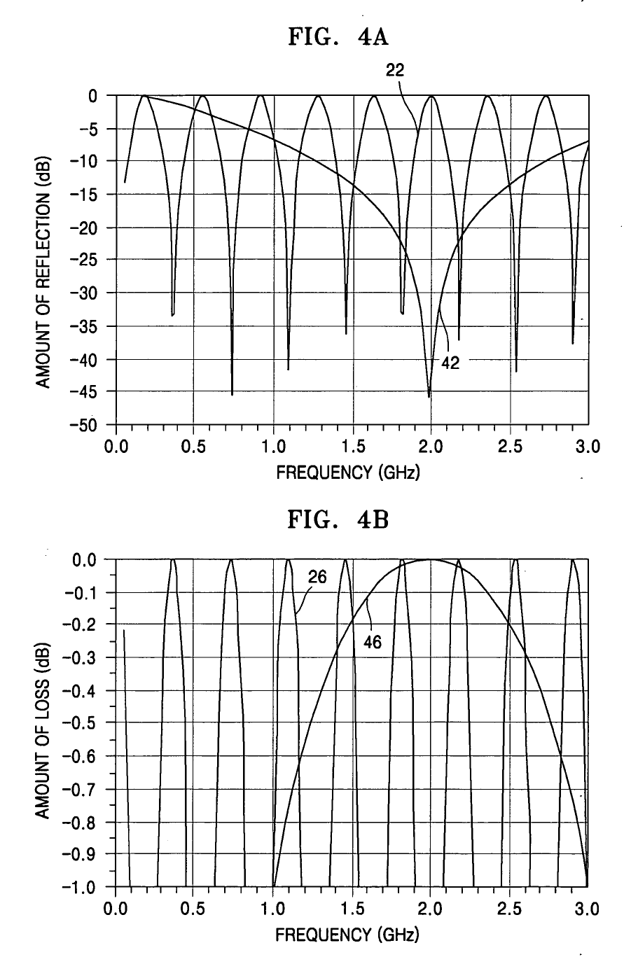

FIGS. 4A and 4B are graphs illustrating an amount of RF signal reflection, and the amount of RF signal loss when a capacitor 36 is connected to a point that is spaced by ¼ of the RF signal wavelength λ from point A of the RF line 34 connected to the DC line 35 for a DC test versus when no capacitor 36 is present, respectively. For example, a target frequency of the RF signal is 2 GHz and ¼ of the RF signal wavelength is 20 mm.

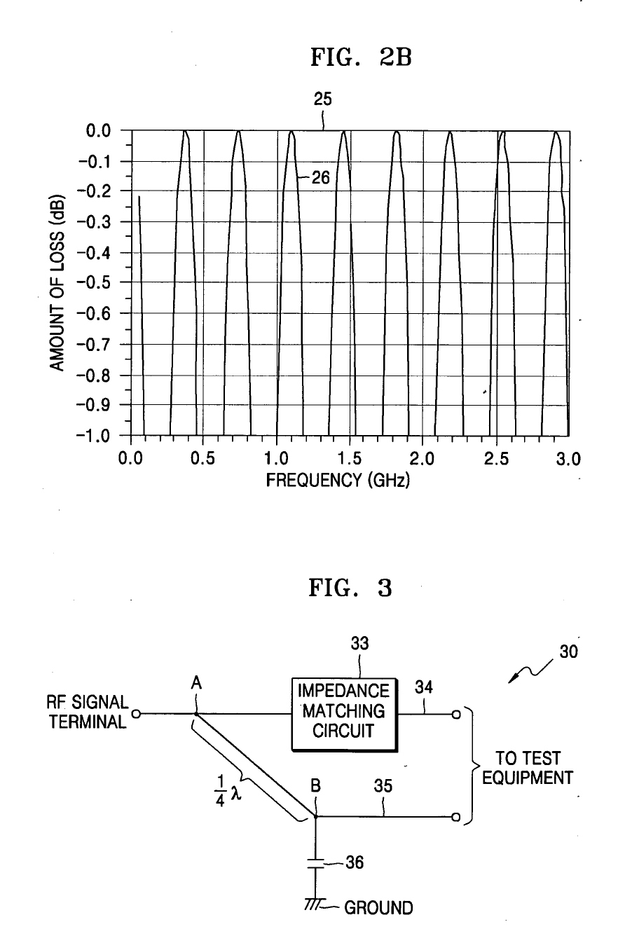

Referring to FIG. 4A, near the frequency of 2 GHz, the amount of reflection 22 is large when the DC line 35 is present without the capacitor 36; but the amount of reflection 42 is as small similar to that of reflection 21 (FIG. 2A) when the capacitor 36 is present. Referring to FIG. 4B, near the frequency of 2 GHz, the amount of loss 26 is large when the DC line 35 is provided without a capacitor; but the amount of loss 46 is as small as that of a loss 25 (FIG. 2B) when the capacitor 36 is present.

Since a frequency band available for the RF device is 100 MHz, the frequency may provide a positive effect to the RF device to remove resonance in the RF signal at the frequency band of 100 MHz around the frequency of 2 GHz. Accordingly, a frequency band of the RF signal for the RF test may be secured by using a DC line 35 without distorting a RF signal in a test supporting device 30 in which a capacitor 36 is connected to point B that is located ¼ of the RF signal wavelength from point A.

If a plurality of the RF lines 34 are connected to the RF device on a test board, the capacitor 36 should not be connected to point B, because the impedance matching circuit 33 must be provided closest to the RF device. If a plurality of the RF lines 34 are connected to the RF device, it may be difficult to provide a space for connection of the capacitor around the RF device. In this case, the capacitor 36 may be connected to a point of the DC line that is located one of ¾, 5/4, 7/4, etc., of the RF signal wavelength λ from point A.

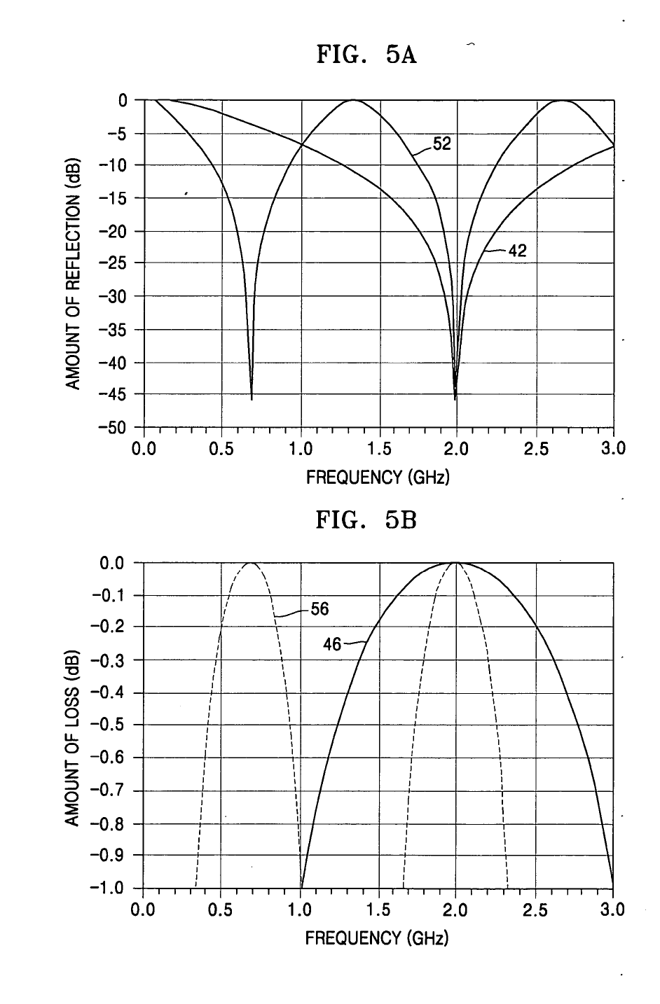

FIGS. 5A and 5B are graphs illustrating variations in the amount of RF signal reflection, and the amount of RF signal loss when a capacitor is connected to a point of a DC line that is located ¼ of a RF signal wavelength λ from point A versus when the capacitor is connected to a point of the DC line that is located 4/3 of the RF signal wavelength λ from point A, respectively.

Referring to FIG. 5A, near the frequency of 2 GHz, a frequency band of the RF signal 42 for the RF test when the capacitor 36 is connected to a point of the DC line 35 that is located ¼ of the RF signal wavelength λ from point A, is wider than that of a RF signal 52 for the RF test when the capacitor 36 is connected to the point of the DC line 35 that is located ¾ of the RF signal wavelength λ from point A. Similarly, referring to FIG. 5B, a frequency band 46 of the RF signal when the capacitor 36 is connected to the point of the DC line 35 that is located ¼ of the RF signal wavelength λ from point A, is wider than that of the RF signal 56 when the capacitor 36 is connected to the point of the DC line 35 that is located ¾ of the RF signal wavelength λ from point A. In other words, the farther a capacitor is located from point A, the longer the phase of the RF signal. Accordingly, the shorter the distance between a capacitor and point A, the better the transmission characteristics of and frequency band available for the RF signal.

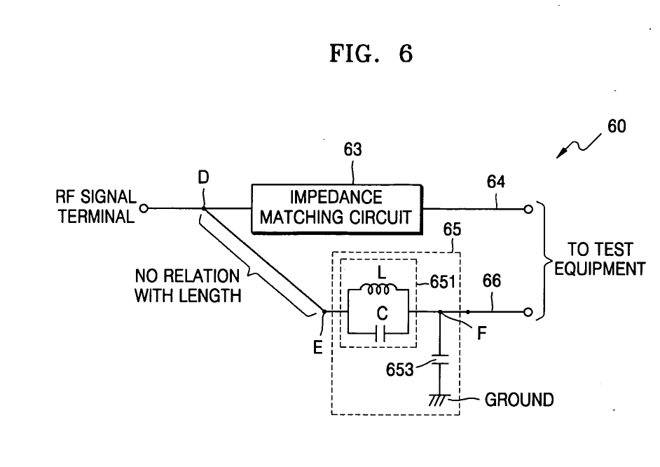

FIG. 6 is a block diagram of a test supporting device 60 according to another example embodiment of the present invention capable of improving transmission characteristics of an RF signal irrespective of a location of a capacitor. Referring to FIG. 6, operations of an RF line 64, a DC line 66, and an impedance matching circuit 63 of the test supporting device 60 may be similar to those of the RF line 34, the DC line 35, and the impedance matching circuit 33 illustrated in FIG. 3, respectively. Therefore, for brevity those elements will not be described in detail. The test supporting device 60 may further include a circuit 65 including a capacitor 653 and an auxiliary circuit 651.

The DC line 66 may connected to a point D of the RF line 64 between an RF signal terminal of an RF device (not shown) and the impedance matching circuit 63. The capacitor 653 may be connected between the DC line 66 and ground.

The auxiliary circuit 651 may be provided at a point in the DC line 66, and may include an inductor L and an auxiliary capacitor C. The inductor L may be connected between a point F of the DC line 66 to which the capacitor 653 may be connected, and a point E of the DC line 66 which may be separated by the insertion of the auxiliary circuit 65. The capacitor C and the inductor L may be connected in parallel.

The capacitor 653 and the auxiliary circuit 651 may cancel oscillations in the RF signal during an RF test, thereby allowing the DC line 66 connected to the RF line 64 to act as an open stub. The inductance of the inductor L and the capacitance of the auxiliary capacitor C may be determined by a distance between point D of the RF line 64 connected to the DC line 66 and point E of the DC line 66 into which the inductor L and the auxiliary capacitor C may be inserted. Similar to the capacitor 36 of FIG. 3, the capacitance of the capacitor 653 may be increased within a range that does not cause distortion of the DC signal.

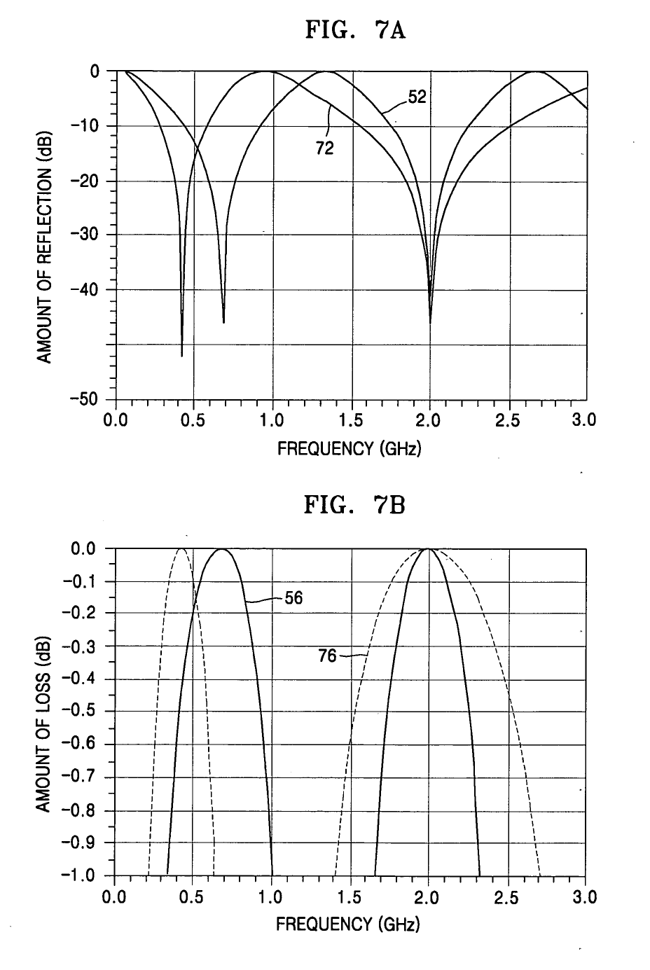

FIGS. 7A and 7B are graphs illustrating an amount of RF signal reflection and RF signal loss when only a capacitor is present in a test supporting device 60 versus when both a capacitor and an auxiliary circuit are present. Specifically, FIGS. 7A and 7B illustrate cases where a capacitor cannot be provided at a point that is located ¼ of an RF signal wavelength λ from a point D of an RF line to which a DC line is connected.

Referring to FIGS. 7A and 7B, near a frequency of 2 GHz, a frequency band available for the RF test when only a capacitor 653 is present in a test supporting device 60 at point F that is located 60 mm, e.g., ¾ of an RF signal wavelength λ, from point D (see 52 and 56), is narrower than when an auxiliary circuit 651 is further present in the test supporting device 60 at a point that is located 25 mm from point D (see 72 and 76 ).

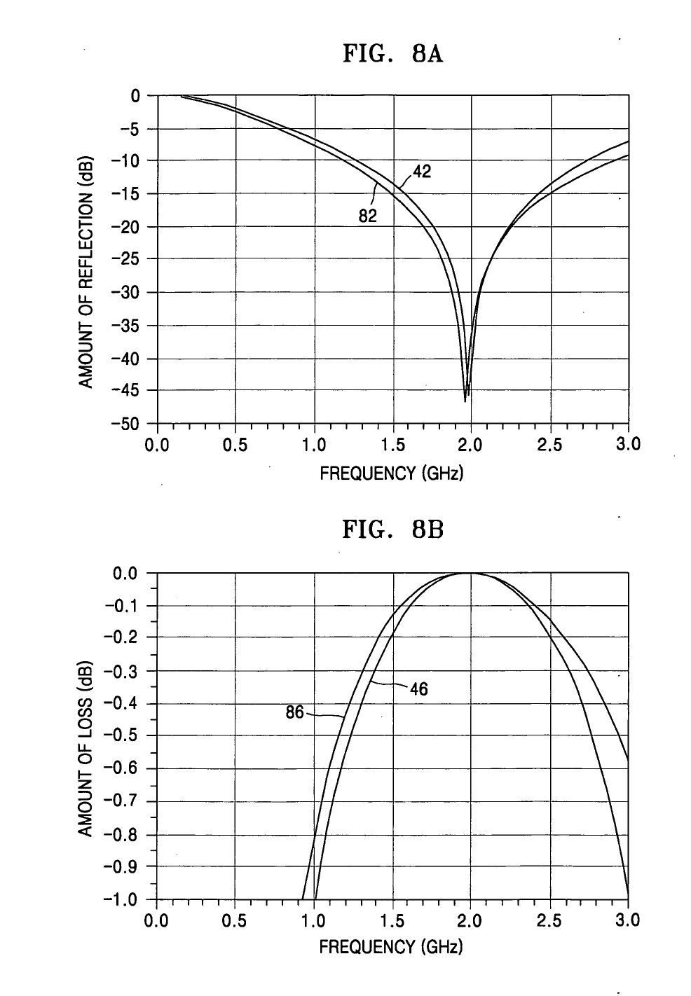

FIGS. 8A and 8B are graphs illustrating an amount of RF signal reflection and RF signal loss when only a capacitor 653 is present in a test supporting device 60 versus when both the capacitor 653 and an auxiliary circuit 651 are present. Specifically, FIGS. 8A and 8 B illustrate cases where the capacitor 653 may be provided at a point that is located less than ¼ of the RF signal wavelength λ from point D of the RF line 64 to which the DC line 66 is connected. Referring to FIGS. 8A and 8B, near a frequency of 2 GHz, the amounts of RF signal reflection and RF signal loss when only the capacitor 653 is connected to point E that is located 20 mm, e.g., ¼ of the RF signal wavelength λ, from the point D (see 42 and 46), are almost equal to those of RF signal reflection and RF signal loss when the auxiliary circuit 651 is further connected to point H (not shown) that is located 10 mm from point D (see 82 and 86). In other words, even if the capacitor 653 and the auxiliary circuit 651 are inserted into a point of the DC line 66 irrespective of the RF signal wavelength, the DC line 66 connected to the RF line 64 may act as an open stub. In the case that a plurality of RF lines 64 may be connected to an RF device on a test board, and thus, a capacitor cannot be connected to a point that is located 20 mm, e.g., ¼ of the RF signal wavelength, from point D, if the capacitor 653 and the auxiliary circuit 651 may be inserted at another point of the DC line 66, e.g., a point located 25 mm from point D, and so the frequency band of the RF signal for the RF test may be secured by the test supporting device according to example embodiments of the present invention (see 72 of FIG. 7A and 76 of FIG. 7B).

As described above, in example embodiments of the present invention, a frequency band of an RF signal for a RF test may be conducted without causing resonance in the RF signal even when a DC line is added on an RF line in a test supporting device. Also, a capacitor may be provided to act as an open stub at a desired position of the DC line. If a capacitor is provided at an arbitrary point of the DC line, an auxiliary circuit that may include an inductor L and an auxiliary conductor C may be required.

As described above, a test supporting device according to example embodiments of the present invention may be capable of suppressing resonance in an RF signal even when a DC line for a DC test is added to an RF line. Therefore, it may be possible to perform both an RF test and a DC test using only a test supporting device, and further, it may be possible to detect a faulty RF signal terminal of an RF device.

While the present invention has been particularly shown and described with reference to example embodiments thereof, it will be understood by those skilled in the art that various changes in form and details may be made therein without departing from the scope of the example embodiments of the present invention.

What is claimed is:

1. A test supporting device comprising:
a radio frequency line;
a direct current line connected to the radio frequency line; and
a capacitor connected between the direct current line and ground,
wherein a radio frequency signal and a direct current signal received from a radio frequency signal terminal are transmitted via the radio frequency line and the direct current line, respectively.

2. The test supporting device of claim 1, wherein the direct current line acts as an open stub due to the capacitor.

3. The test supporting device of claim 1, wherein the capacitor is located along the direct current line depending on a frequency of the radio frequency signal and characteristics of the radio frequency line.

4. The test supporting device of claim 1, wherein the capacitor is located along the direct current line ¼ of a wavelength of the radio frequency signal from a point of the radio frequency line to which the direct current line is connected.

5. The test supporting device of claim 1, wherein the capacitor is located along the direct current line ¾ of a wavelength of the radio frequency signal from a point of the radio frequency line to which the direct current line is connected.

6. The test supporting device of claim 1, wherein a capacitance of the capacitor is within a range that does not cause distortion of the direct current signal.

7. The test supporting device of claim 1, further comprising an auxiliary circuit along the direct current line, the auxiliary circuit changing resonance characteristics of the radio frequency signal.

8. The test supporting device of claim 7, wherein the direct current line acts as an open stub due to the capacitor and the auxiliary circuit.

9. The test supporting device of claim 7, wherein the auxiliary circuit is located along the direct current line.

10. The test supporting device of claim 7, wherein the auxiliary circuit includes:
an inductor connected between a point of the direct current line to which the capacitor is connected, and a point of the direct current line which is separated from the point of the direct current line to which the capacitor is connected by the insertion of the auxiliary circuit; and
an auxiliary capacitor connected to the inductor in parallel.

11. The test supporting device of claim 10, wherein an inductance of the inductor and a capacitance of the auxiliary capacitor are determined by a distance between a point of the radio frequency line to which the direct current line is connected, and a point of the direct current line into which the inductor and the auxiliary capacitor are inserted.

12. The test supporting device of claim 7, further comprising an impedance matching circuit along the radio frequency line.

13. The test supporting device of claim 12, wherein the direct current line is connected to the radio frequency line between the radio frequency signal terminal and the impedance matching circuit.

14. A test method comprising:
measuring a radio frequency signal received from a radio frequency signal terminal using a radio frequency line connected to a direct current line; and
measuring a direct current signal received from the radio frequency signal terminal using the direct current line, wherein a capacitor is connected between the direct current line and a ground.

15. The test method of claim 14, wherein the direct current line acts as an open stub due to the capacitor.

16. The test method of claim 14, wherein a location of the capacitor along the direction current line is determined by a frequency of the radio frequency signal and characteristics of the radio frequency line.

17. The test method of claim 14, wherein the capacitor is located along the direct current line ¼ of a wavelength of the radio frequency signal from a point of the radio frequency line to which the direct current line is connected.

18. The test method of claim 14, wherein the capacitor is located along the direct current line ¾ of a wavelength of the radio frequency signal from a point of the radio frequency line to which the direct current line is connected.

19. The test method of claim 14, wherein a capacitance of the capacitor is within a range that does not cause distortion of the direct current signal.

20. The test method of claim 14, which uses an inductor and an auxiliary capacitor inserted in parallel at a point on the direct current line.

21. The test method of claim 20, wherein the inductor and auxiliary capacitor change resonance characteristics of the radio frequency signal.

22. The test method of claim 20, wherein the direct current line acts as an open stub due to the capacitor and the inductor and auxiliary capacitor.

23. The test method of claim 20, wherein an inductance of the inductor and a capacitance of the auxiliary capacitor are determined by a distance between a point of the radio frequency line to which the direct current line is connected, and a point of the direct current line into which the inductor and the auxiliary capacitor are inserted.

24. The test method of claim 20, which uses an impedance matching circuit inserted into the radio frequency line.

25. The test method of claim 24, wherein the direct current line is connected to the radio frequency line between the radio frequency signal terminal and the impedance matching circuit.
